(19) United States
(12) Patent Application Publication
(10) Pub. No.: US 2020/0300804 A1
(43) Pub. Date: Sep. 24, 2020

(54) SENSOR

(71) Applicant: KABUSHIKI KAISHA TOSHIBA, Minato-ku (JP)

(72) Inventors: Tatsuro SAITO, Kawasaki (JP); Atsunobu ISOBAYASHI, Yokohama (JP); Yoshiaki SUGIZAKI, Fujisawa (JP)

(73) Assignee: KABUSHIKI KAISHA TOSHIBA, Minato-ku (JP)

(21) Appl. No.: 16/567,124

(22) Filed: Sep. 11, 2019

(30) Foreign Application Priority Data
Mar. 19, 2019 (JP) 2019-051716

(51) Int. Cl. G01N 27/414

(52) U.S. Cl. CPC G01N 27/4141; H01L 29/1606

(57) ABSTRACT

According to one embodiment, a sensor is disclosed. The sensor includes a predetermined number of vesicles and a first detector. The first detector includes a channel film that connects with the vesicles, and a trench provided for connecting the channel film with the vesicles.

### CROSS-REFERENCE TO RELATED APPLICATIONS

This application is based upon and claims the benefit of priority from Japanese Patent Application No. 2019-051716, filed Mar. 19, 2019, the entire contents of which are incorporated herein by reference.

### FIELD

Embodiments described herein relate generally to a sensor.

### BACKGROUND

There is a demand of improving the performance of sensors using a molecular identification function of a substance relating to a living body or an artificial matter.

### BRIEF DESCRIPTION OF THE DRAWINGS

FIG. 1 is a block diagram showing a sensor according to a first embodiment.

FIG. 2 is a plan view showing the sensor according to the first embodiment.

FIG. 3 is a cross section taken along III-III in FIG. 2.

FIG. 4 is a cross section taken along IV-IV in FIG. 2.

FIG. 5 is a diagram schematically showing an example of vesicle.

FIGS. 6A and 6B are diagrams showing a method of adsorbing a vesicle on a graphene film in a trench.

FIG. 7 is a diagram illustrating a sensor according to a second embodiment.

FIG. 8 is a diagram illustrating a sensor according to a third embodiment.

FIGS. 9A and 9B are diagrams illustrating a sensor according to a fourth embodiment.

FIGS. 10A, 10B and 10C are diagrams illustrating a sensor according to a fifth embodiment.

FIG. 11 is a diagram illustrating a sensor according to a sixth embodiment.

FIGS. 12A and 12B are diagrams illustrating a sensor according to a seventh embodiment.

### DETAILED DESCRIPTION

In general, according to one embodiment, a sensor is disclosed. The sensor includes a predetermined number of vesicles and a first detector. The first detector includes a channel film that connects with the vesicles, and a trench provided for connecting the channel film with the vesicles.

Embodiments will be described hereinafter with reference to the accompanying drawings. The drawings are schematic or conceptual drawings, and dimensions and ratios are not necessarily the same as those in reality. Further, in the drawings, the same reference symbols (including those having different subscripts) denote the same or corresponding parts, and overlapping explanations thereof will be made as necessary. In addition, as used in the description and the appended claims, what is expressed by a singular form shall include the meaning of “more than one”.

### First Embodiment

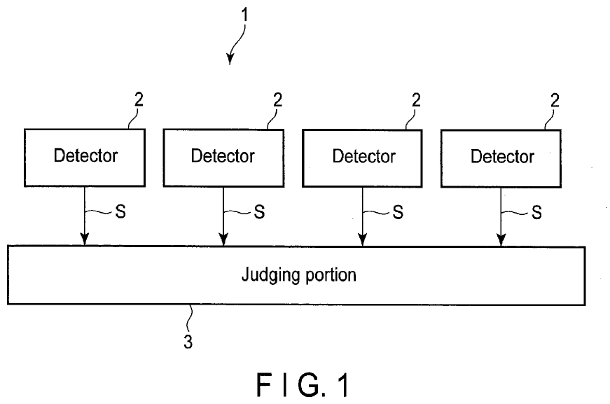

FIG. 1 is a block diagram schematically showing a sensor 1 which detects gas, according to the first embodiment. Here, the gas is made from, for example, odor molecules such as of alcohol or acetaldehyde. Note that the gas may as well be of odorless molecules.

The sensor 1 includes detectors 2 and a judging portion 3. FIG. 1 shows a plurality of detectors 2, but the number of the detectors 2 may be one. Each of the detectors 2 outputs a detection signal S that indicates whether the gas is detected or not. When the detector 2 detects the gas, the detector 2 outputs a detection signal S that has a level of a predetermined value (threshold) or higher. When the detector 2 does not detect the gas, the detector 2 outputs a detection signal S that has a level lower than the threshold.

Note that, for simplicity, FIG. 1 shows only four detectors. In practice, the number of detectors is, for example, about one million. The detectors (detector cells) are arranged, for example, two-dimensionally in a matrix. The present embodiment is explained on the assumption that each detector detects the same kind (molecular structure) of gas.

A plurality of detection signals S are input to the judging portion 3. The judging portion 3 judges the number of gaseous molecules that are detection targets based on the signals S. For example, the judging portion 3 judges each of the detection signals input per unit time as to whether it has a level at the threshold or higher, and determines the total number of detection signals at a level of the threshold or higher, as the number of the gaseous molecules detected per unit time.

Detection signals obtained when the gas is detected can be easily discriminated from detection signals obtained when the gas is not detected by using, for example, a resistance measurement means (for example, Wheatstone bridge). For that reason, each of the detected levels can be easily and accurately judged as to whether it is at the threshold or higher. Thus, according to present embodiment, the sensor 1 with such an improved performance can be provided that the number of detected target gaseous molecules can be quantitatively obtained easily.

Note that, as described above, in FIG. 1, the number of the detectors 2 may be one, but if a plurality of detectors are employed as in present embodiment, the number of gaseous molecules can be quantitatively obtained easily.

Next, a concrete structure of the sensor 1 of present embodiment will be described.

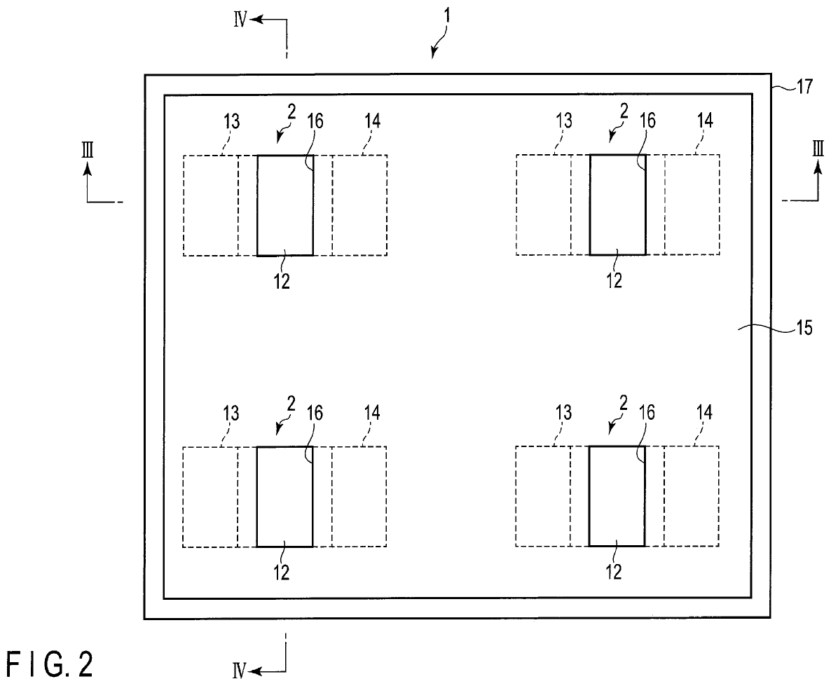

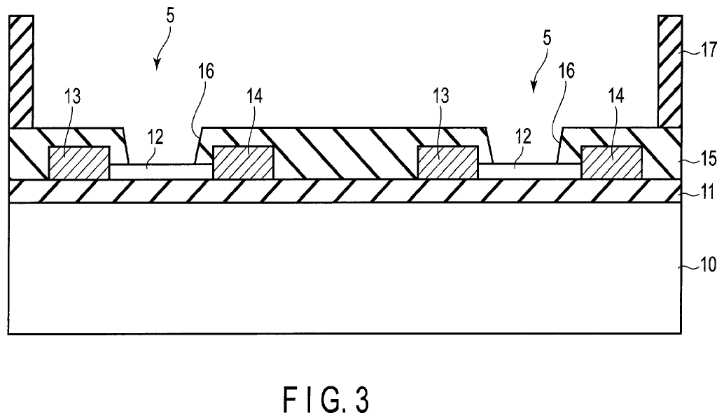

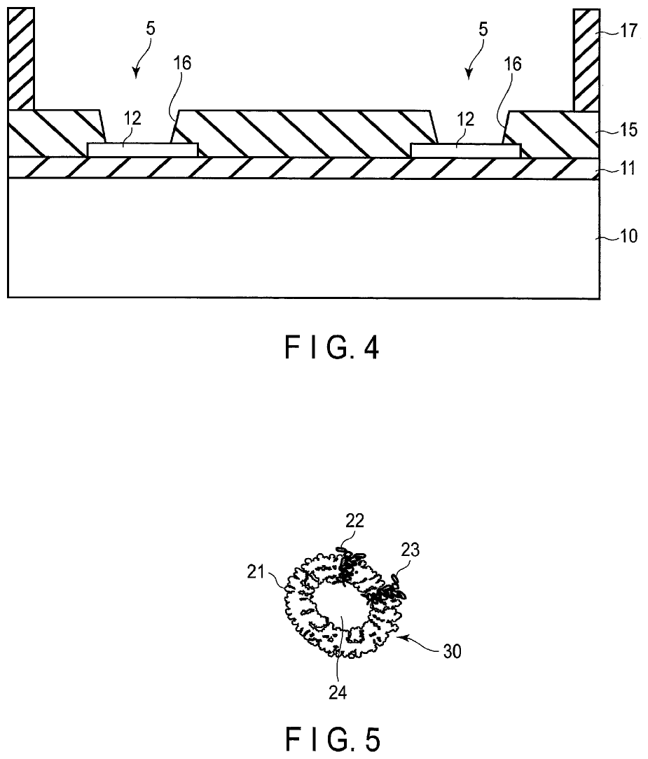

FIG. 2 is a plan view showing the sensor 1 of present embodiment. FIG. 3 is a cross section taken along III-III in FIG. 2, and FIG. 4 is a cross section taken along IV-IV in FIG. 2.

As shown in FIGS. 3 and 4, the sensor 1 includes a substrate 10, an insulating film 11 provided on the substrate 10, and detectors 2 provided on the insulating film 11.

The substrate 10 includes a semiconductor substrate. The semiconductor substrate is, for example, a silicon (Si) substrate or a silicon carbide (SiC) substrate. Note that, in place of the semiconductor substrate, a substrate containing a silicon oxide (for example, SiO₂), silicon nitride (for example, Si₃N₄), or a polymeric material may be used. The insulating film 11 is, for example, a silicon oxide film.

The detectors 2 each contain a detecting element 5. The detecting element 5 includes the insulating film 11, a graphene film (channel film) 12, a drain electrode 13, a source electrode 14, and a protective film 15.

On the insulating film 11, the graphene film (channel film) 12, the drain electrode 13, the source electrode 14, and the protective film 15 are provided. The insulating film 11 is, for example, a silicon oxide film.

One end of each graphene film 12 is connected to the drain electrode 13, the other end of the graphene film 12 is connected to the source electrode 14, and the graphene film 12 connects the drain electrode 13 and the source electrode 14 to each other. The graphene film 12 contains a monolayer grapheme sheet or multi-layer graphene sheet. In place of the graphene film 12, a silicon film or a carbon nanotube can be use as well. Moreover, a film containing the catalyst of graphene (catalyst film) may be provided between the insulating film 11 and the graphene film 12. The catalyst film serves to facilitate the formation of the graphene film 12.

The drain electrode 13 or the source electrode 14 is connected to the judging portion 3 shown in FIG. 1. The protective film 15 is formed on the graphene film 12, the respective drain electrode 13 and the source electrode 14. The protective film 15 includes a trench (groove) 16 which linearly exposes a part of an upper surface of the graphene film 12. The dimension of trench 16 is set so that a predetermined number of vesicles can be adsorbed on the exposed surface of the protective film 15 by chemical bonding. The part of upper surface of graphene film 12 may be exposed into some other shape, for example, dot (rectangular). The protective film 15 is, for example, an insulating film such as a silicon nitride film. The protective film 15 protects the drain electrode 13 and the source electrode 14 from a measurement liquid.

A wall structure 17 enclosing the detecting elements 5 is provided on the protective film 15 such that the trench 16 is exposed. A material of the wall structure 17 is an insulator (for example, silicon oxide, silicon nitride, or polymeric material). The protective film 15 and the wall structure 17 form a well which reserves a measurement liquid in the trench 16. The wall structure 17 define side walls of the well, and the protective film 15 defines a bottom surface of the well. In place of the well, a passage structure including a flow path may be used.

The substrate 10 includes a semiconductor substrate. The semiconductor substrate is, for example, a silicon (Si) substrate or a silicon carbide (SiC) substrate. Note that, in place of the semiconductor substrate, a substrate containing a silicon oxide (for example, SiO₂), a silicon nitride (for example, Si₃N₄), or a polymeric material may be used. The insulating film 11 is provided on the substrate 10.

The detecting element 5 is a field-effect type transistor (FET) element which includes the insulating film 11, the graphene film (channel film) 12, the drain electrode 13, the source electrode 14 and the protective film 15, and outputs a current (drain current). Note that, in place of the FET type element, a resistor element or a capacitor element can be used as well. The capacitor element includes, for example, micro-electromechanical systems (MEMS).

A measurement liquid (not shown) containing the gas is supplied into the well (or the flow path), and thus the measurement liquid is supplied in the trenches 16 of the detecting elements 5. The measurement liquid contains a vesicle whose electrical characteristic such as an ion concentration changes when the gas adheres to the vesicle.

FIG. 5 is a diagram schematically showing an example of a vesicle 30.

The vesicle 30 is an endoplasmic reticulum formed of a lipid bilayer and containing a liquid inside. In more detail, the vesicle 30 includes a spherical shell-like lipid structure 21 formed from of a phospholipid bilayer, an olfactory receptor (a first ion-channel receptor) 22 embedded in the lipid structure 21 and adsorbing gas, an olfactory receptor coreceptor (orco) 23 embedded in the lipid structure 21 and a liquid 24 contained in the lipid structure 21. The olfactory receptor 22 and the orco 23 contain proteins and can migrate in the lipid structure 21.

When the gas is adsorbed to the olfactory receptor 22, the olfactory receptor 22 and the orco 23 migrate so as to form the first ion channel (now shown) which allows ions to pass into the lipid structure 21.

When the ions flow into the lipid structure 21 through the first ion channel, the ion density on the graphene film 12 increases and the level of drain current (detection current) increases. The judging portion (not shown) can acquire the number of gaseous molecules quantitatively based on the level of the drain current (detection current) input from each detecting element.

As the volume (size) of the vesicle 30 is less, the degree of variation in the electric field in the surface of the vesicle 30, associated with the variation in ion density 30 becomes higher. Therefore, as the volume (size) of the vesicle 30 is less, the variation in current can be detected with higher sensitivity. When the volume (size) of a vesicle is defined by its diameter, the value of the diameter is, for example, 50 nm or greater but 1 μm or less.

The trenches 16 shown in FIGS. 3 and 4 have dimensions corresponding to the size of one vesicle. That is, one vesicle can enter one trench 16 on the graphene film 12 therein, but two or more vesicles cannot enter.

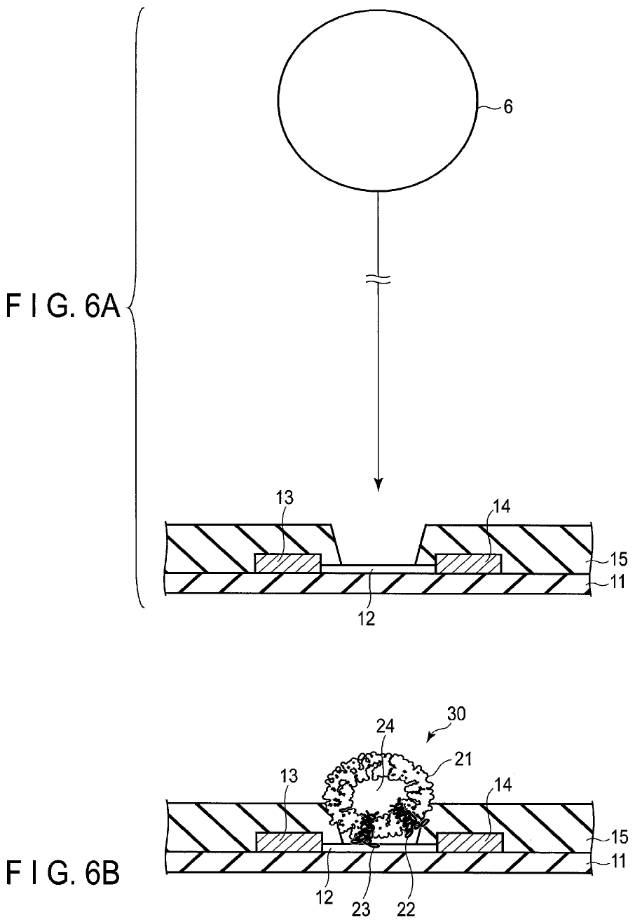

FIGS. 6A and 6B are diagrams for illustrating a method of adsorbing a vesicle 30 on the graphene film 12 in the trench 16. In this method, an olfactory receptor and an orco, which contain proteins that nonspecifically adsorb, are used. That is, a nonspecifically adsorbable vesicle is used.

As shown in FIG. 6A, a liquid 6 having a high concentration of vesicles is dropped towards the trench 16. As described above, the trench 16 has dimensions corresponding to the size of one vesicle 30, one vesicle 30 is adsorbed by chemical bonding on the graphene film 12 in the trench 16, as shown in FIG. 6B.

In present embodiment, nonspecifically adsorbable vesicles 30 are used, and thus vesicles 30 may be located not only on the protective film 15 in the trench 16, but also on the protective film 15 outside the trench 16. However, such vesicles 30 located on the protective film 15 do not substantially affect the drain current, i.e., the gas detection accuracy.

Note that in place of the vesicle-containing measurement liquid, it is also possible to supply a measurement solution which does not contain vesicles, in the well in the state where one vesicle is adsorbed on the graphene film in the trench. That is, such a sensor may as well used, in which the vesicle 30 is preliminarily adsorbed on the graphene film in the trench.

In the following embodiments, for simplicity of explanation, types of sensors are not particularly distinguished as to whether vesicles are not adsorbed in advance on the graphene films in trenches or vesicles are adsorbed in advance. In the former case of sensors, a vesicle-containing measurement liquid is used. In the latter case of sensors, a measurement liquid which does not contain vesicles is used.

In the present embodiment, the graphene film 12 is used as a channel film, but a film comprising Si (silicon), Ge (gallium), group III-V element compound or C (carbon) may be used as a channel film. Furthermore, a film comprising substance that contains at least one of graphene, Si, Ge, group III-V element compound and C may be as a channel film.

### Second Embodiment

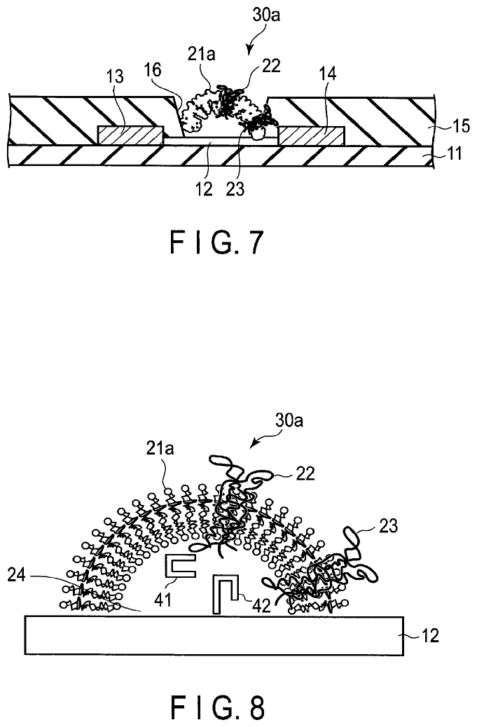

FIG. 7 is a diagram illustrating a sensor according to the second embodiment.

Present embodiment is different from the first embodiment in that a vesicle 30a containing a developed lipid structure 21a is used. That is, in the first embodiment, as shown in FIG. 5, the lipid structure 21 has a spherical shell shape and the lipid structure 21 contains a liquid 24, whereas in present embodiment, as shown in FIG. 7, the lipid structure 21 such a shape that a part of a spherical shell is cut out and the lipid structure 21 does not contain the liquid 24.

The vesicle 30a is obtained by, for example, dropping a measurement liquid of a high vesicle concentration towards the trench 16 under a condition that the lipid structure should develop.

In present embodiment, ions flowing in from the ion channel are brought into contact with the graphene film 12 directly, and therefore the variation in ion density (drain current) can be detected at high sensitivity.

### Third Embodiment

FIG. 8 is a diagram illustrating a sensor according to the third embodiment.

Present embodiment is different from the second embodiment in that a liquid (not shown) between the graphene film 12 (the first structure) and the vesicle 30a (the second structure) contains a first substance 41 and a second substance 42. The second substance 42 is bonded to the graphene film 12.

The first substance 41 selectively bonds to a predetermined ion which has passed through the first ion channel, that is, an ion that is detection target (first ion). The first ion is, for example, a calcium ion (Ca²⁺). When the first ion is a calcium ion, the first substance 41 contains, for example, calmodulin.

The second substance 42 selectively bonds to a substance in which the first ion and the first substance 41 bond each other. When the first substance 41 is calmodulin, the second substance 42 contains, for example, calmodulin-dependent protein kinase.

Here, ions other than the first ion (ions which does not correspond to the gas of detection target) as well may pass the first ion channel. However, in present embodiment, with the first substance 41 and the second substance 42, which have the above-described characteristics, the increase in the drain current (detection current) resulting from the first ion can be detected efficiently even when the ions other than the first ion may as well pass the first ion channel. In other words, the increase in the drain current (noise) resulting from the ions other than the first ion can be effectively suppressed. Therefore, according to present embodiment, the accuracy of detection gas can be improved.

Note that in FIG. 8, the second substance 42 is bonded to the graphene film 12, but the second substance 42 may float in the liquid. Moreover, the first substance 41 and the second substance 42 may be bonded to the olfactory receptor 22, or the first substance 41 and the second substance 42 may be bonded to the orco 23. Further, the first substance 41 may be bonded to the olfactory receptor 22, whereas the second substance 42 may be bonded to the orco 23. Conversely, the first substance 41 may be bonded to the orco 23, whereas the second substance 42 may be bonded to the olfactory receptor 22.

### Fourth Embodiment

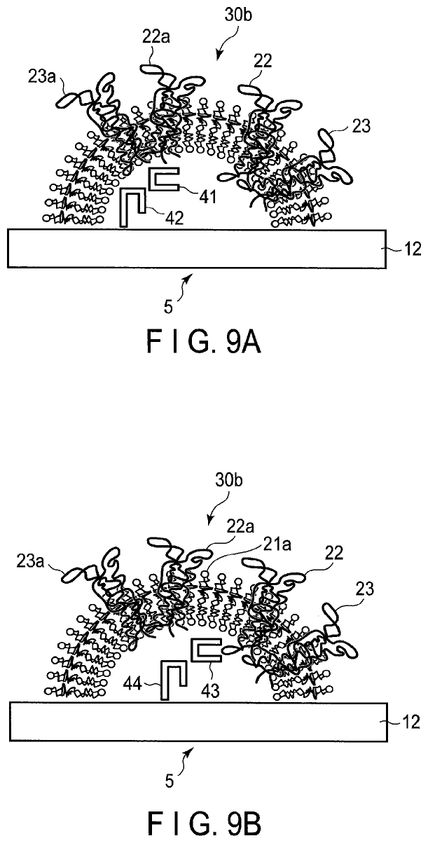

FIGS. 9A and 9B are diagrams illustrating a sensor according to the fourth embodiment.

In present embodiment, the case where a vesicle 30b which forms a first ion channel and a second ion channel is used. The vesicle 30b is developed.

Ion which passes the first ion channel (first ions) is different in kind from ion which passes the second ion channel (second ions). For example, the first ion and the second ion are a calcium ion and a potassium ion (K+), respectively.

The vesicle 30b contains a lipid structure 21a, an olfactory receptor 22, an olfactory receptor (a second ion channel receptor) 22a, an orco 23 and an orco 23a. When a gaseous molecule is adsorbed to the olfactory receptor 22, the olfactory receptor 22 and orco 23 migrate so as to form the first ion channel which allows the first ion to pass through. In addition, when a gaseous molecule is adsorbed to the olfactory receptor 22a, the olfactory receptor 22a and the orco 23a migrate so as to form the second ion channel which allows the second ion, which is different in kind from the first ion, to pass.

Each detector of present embodiment contains a detecting element 5 shown in FIG. 9A and a detecting element 5 shown in FIG. 9B. The liquid between the graphene film 12 of the detecting element 5 shown in FIG. 9A and the developed vesicle 30b contains the first substance 41 and the second substance 42. The liquid between the graphene film 12 of the detecting element 5 shown in FIG. 9B and the developed vesicle 30b contains the third substance 43 and the fourth substance 44. The third substance 43 selectively bonds to the second ion having passed through the second ion channel. The fourth substance 44 selectively bonds to a substance in which the second ion and the third substance 43 bond each other.

With use of the first substance 41 to the fourth substance 44, which have the above-described characteristics, the detecting element 5 of FIG. 9A selectively detects the first ion, and the detecting element 5 of FIG. 9B selectively detects the second ion.

Thus, even if a vesicle 30b which forms the first and second ion channels is used, the drain current resulting from the first ion and the drain current resulting from the second ion can be detected, respectively, at high sensitivity. Note that when using a vesicle which forms three or more ion channels, a technique similar to that described above can be used to detect drain current at high sensitivity.

### Fifth Embodiment

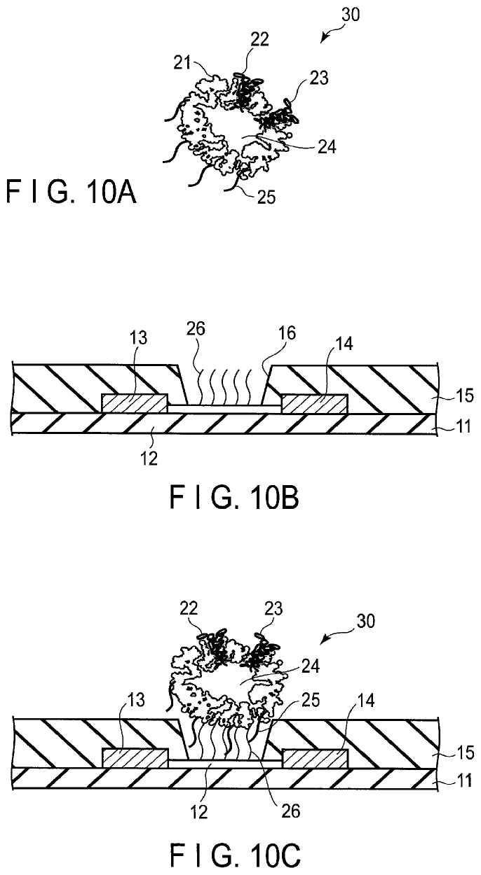

FIGS. 10A to 10C are diagrams illustrating a sensor according to the fifth embodiment.

In present embodiment, as shown in FIG. 10A, a probe marker 25 is provided on a vesicle 30. The probe marker 25 contains a substance which forms, for example, elements 21 to 24 (for example, protein, sugar chain, lipid). The probe marker 31 may be modified with molecules containing a substance different from the above-mentioned substance.

Further, as shown in FIG. 10B, probes 26 are provided on a graphene film 12 in a trench 16. The probes 26 specifically bond to the probe marker 25. The material of the probe 26 contains an adapter such as a DNA that bonds to a specific protein, sugar chain, proteins such as an antibody, amino acid, or a compound.

When a liquid containing a vesicle 30 provided with the probe marker 31 is dropped towards the trench 16, the probe 26 specifically bonds to the probe marker 25 as shown in FIG. 10C. As a result, the graphene film 12 in the trench 16 is bonded to one vesicle 30 via the probes 26 and the probe marker 25. The vesicle 30 is not bonded to the outside of the trench 16.

### Sixth Embodiment

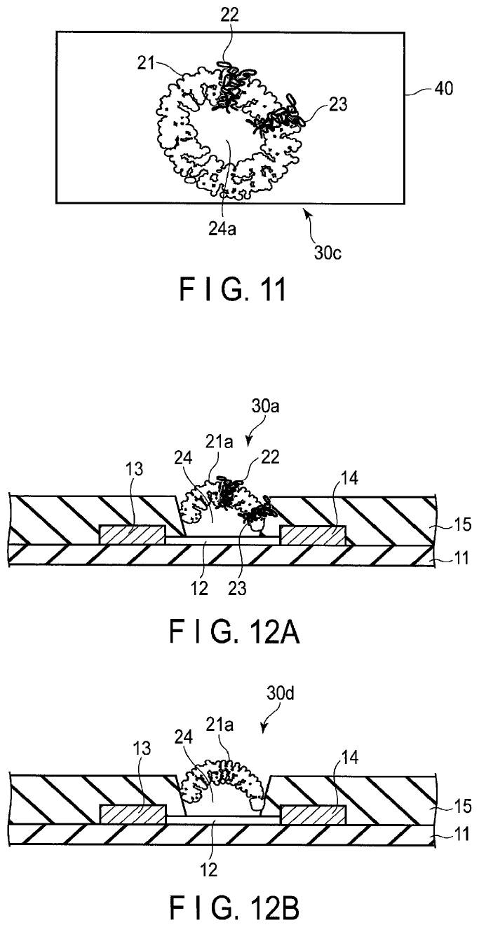

FIG. 11 is a diagram illustrating a sensor according to the sixth embodiment.

In present embodiment, a vesicle 30c containing pure water 24a in its spherical shell-like lipid structure 21 is used. Further, a measurement liquid 40 containing a buffer solution is used. That is, in present embodiment, when the measurement liquid 40 is supplied, the difference in ion concentration between an inside and an outside of the vesicle 30c is adjusted to a certain degree or higher. The buffer solution contains, for example, Dulbecco's phosphate-buffered saline (DPBS).

By regulating the difference of the ion concentration to the certain degree or higher, the change of ion concentration in the vesicle 30c can be large, which is accompanied by opening and closing of the ion channel. Thereby, the variation in drain current (detection current) can be detected with high sensitivity.

### Seventh Embodiment

FIGS. 12A and 12B are diagrams illustrating a sensor according to the seventh embodiment.

In present embodiment, each detector contains a detecting element 5 shown in FIG. 12A and a detecting element 5′ shown in FIG. 12B. A developed vesicle 30d which does not contain an olfactory receptor or orco is adsorbed on the graphene film 12 of the detecting element 5′. As the vesicle 30d does not form an on-channel, the number of ions in the vesicle 30d is substantially constant.

As a result, the ion density on the graphene film 12 of the detecting element 5′ is substantially constant, the level of the drain current of the detecting element 5′ is substantially constant. By using the drain current of the detecting element 5′ as a reference signal, the S/N ratio of detection current can be increased. For example, when the difference between the drain current of the detecting element 5′ and the drain current of the element structure 5c is used as a detection current, the S/N ratio of the detection current can be increased.

Note that, the S/N ratio of the detection signal can be also improved by using a vesicle embedded with a compound through which the ions of the detection targets continue to selectively pass, instead of using the vesicle 30. The compound is, for example, a low-molecular compound such as an ionophore.

Note that, in the first to seventh embodiments, chemical interactions are utilized to adsorb one vesicle on the graphene film in the trench, but electric interactions (for example, electrostatic interaction) may be utilized as well.

Moreover, in the first to seventh embodiments, the vesicle (endoplasmic reticulum) that can open and close the ion channel is used, but in place, a cell that can open and close the ion channel may be used as well. Alternatively, a part of the above mentioned vesicle (endoplasmic reticulum) or a part of the above mentioned cell may be used as well.

Moreover, in the first to seventh embodiments, the odor is detected based on the variation in the ion concentration on the graphene film (the variation in electrical characteristic) accompanied by opening and closing of the ion channel, but the odor may be detected based on variation in the size or shape of vesicle (structural variation) or a structural variation of a member bonded to the vesicle.

Furthermore, the first to seventh embodiments are related to the sensor that detects odor as a detection target, but the embodiments are applicable to a sensor that detect other detection target, for example, gustatory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A sensor comprising:
a predetermined number of vesicles; and
a first detector including a channel film configured to connect with the vesicles, and a trench provided for connecting the channel film with the vesicles.

2. The sensor of claim 1, wherein the first detector is configured to output a signal corresponding to presence or absence of a detection target.

3. The sensor of claim 2, further comprising:
a second detector including a channel film configured to connect with a predetermined number of vesicles, and
a trench provided for connecting the channel film with the vesicles.

4. The sensor of claim 3, wherein each of the first detector and the second detectors is configured to output a signal corresponding to presence or absence of a detection target.

5. The sensor of claim 4, further comprising a judging portion configured to judge the number of detection targets based on the output signal of the first detector and the output signal of second detector.

6. The sensor of claim 4, wherein:
each of the first detector and the second detector includes a first structure in which a current corresponding to the signal flows, and a second structure whose electrical condition changes when the detection target adheres to the second structure,
the first structure includes a drain electrode, a source electrode disposed spaced from the drain electrode, the channel film connecting the drain electrode and the source electrode, and a first insulating film provided on an upper surface of the channel film, covering the drain electrode and the source electrode and including the trench, and
the second structure is provided on the channel film in the trench.

7. The sensor of claim 6, wherein the second structure includes a lipid and a first ion-channel receptor provided in the lipid.

8. The sensor of claim 7, wherein the second structure forms an ion channel through which the first ion passes, when the detection target adheres to the first ion-channel receptor.

9. The sensor of claim 8, wherein the trench has dimensions corresponding to a size of the second structure.

10. The sensor of claim 9, wherein the second structure has an open annular tertiary structure.

11. The sensor of claim 10, wherein each of the first detector and the second detector includes:
a first substance provided between the first structure and the second structure and selectively bonds to the first ion, and
a second substance provided between the first structure and the second structure and selectively bonds to a substance in which the first ion and the first substance bond each other.

12. The sensor of claim 11, further comprising:
a second ion-channel receptor provided in the lipid.

13. The sensor of claim 12, wherein the second structure forms an ion channel through which a second ion being different type from the first ion passes, when the detection target adheres to the second ion-channel receptor.

14. The sensor of claim 13, wherein:
each of the first detector and the second detector includes two first structures, and
with respect to each of the first detector and the second detector,
a first substance that selectively bonds to the first ion and a second substance that selectively bonds a substance in which the first ion and the first substance bond each other are provide between one of the two first structures and the second structure, and
a third substance that selectively bonds to the second ion and a fourth substance selectively bonds to a substance in which the second ion and the second substance bond each other are provide between another one of the two first structures and the second structure.

15. The sensor of claim 3, further comprising a probe provided on the channel film of the second detector and configured to bond to a second structure whose electrical condition changes when the detection target adheres to the second structure.

16. The sensor of claim 15, further comprising a marker provided in the second structure and configured to bond to the probe.

17. The sensor of claim 1, further comprising a third detector configured to output a reference signal.

18. The sensor of claim 2, wherein the detection target include gas.

19. The sensor of claim 18, wherein the gas includes an odor molecule.

20. The sensor of claim 13, wherein the vesicles is one.

21. The sensor of claim 3, wherein the channel film of the first detector and the channel film of the second detector comprises graphene, Si, Ge, group III-V element compound or C, or substance containing at least one of those materials.
